(19) United States
(12) Patent Application Publication
(10) Pub. No.: US 2024/0011184 A1
(43) Pub. Date: Jan. 11, 2024

(54) HIGHLY ORIENTED, SINGLE-CRYSTALLINE LOW-DIMENSIONAL NANOSTRUCTURES, METHOD OF FABRICATION AND DEVICES

(71) Applicant: NATIONAL UNIVERSITY OF SINGAPORE, Singapore (SG)

(72) Inventors: Andrivo RUSYDI, Singapore (SG); Eng Soon TOK, Singapore (SG); Bin Leong Edwin ONG, Singapore (SG)

(21) Appl. No.: 18/042,007

(22) PCT Filed: Aug. 17, 2021
(86) PCT No.: PCT/SG2021/050480

§ 371 Date: Feb. 17, 2023

(30) Foreign Application Priority Data
Aug. 17, 2020 (SG) 10202007864S

(51) Int. Cl. C30B 23/00; C30B 23/06; C30B 29/02

(52) U.S. Cl. CPC C30B 23/002; C30B 23/063; C30B 23/066; C30B 29/02

(57) ABSTRACT

A method of fabricating low dimensional nanostructures on a growth substrate, a single-crystalline low dimensional nanostructure, and a device comprising one or more single-crystalline low dimensional nanostructures. The method comprises fabricating low dimensional nanostructures on a growth substrate using physical vapor deposition, PVD, in a vacuum chamber wherein the low dimensional nanostructures are formed as a strain relief mechanism promoted by a similarity of crystal structure 2-dimensional symmetry between the growth substrate and the low dimensional nanostructures to be grown and a lattice mismatch between the growth substrate and the low dimensional nanostructures to be grown.

### FIELD OF INVENTION

The present invention relates broadly to highly oriented, single-crystalline low-dimensional nanostructures, method of fabrication and devices, and particularly to strongly-correlated electron systems comprising of self-organized single-crystal low-dimensional nanostructures with spin-polarized, orbital-ordered plasmons.

### BACKGROUND

Any mention and/or discussion of prior art throughout the specification should not be considered, in any way, as an admission that this prior art is well known or forms part of common general knowledge in the field.

Many-body electronic correlations and spectral weight transfer play important roles in driving exotic phenomena such as high-temperature superconductivity, colossal magneto resistivity, and metal-insulator transition, in strongly correlated electron systems. An exotic but less-explored phenomenon is a spin plasmon, a quasiparticle due to a quantum oscillation of spin density, in strongly correlated electron systems proposed by Sir Mott in 1936. The spin plasmon is important for both new fundamental science and opening entirely novel future applications. For instance, it is expected to bridge between spintronics and plasmonics and consequently, the spin-photon interaction may occur in such small-scale of magnetic domain and would therefore be much faster and more energy-efficient than the electron-photon interaction.

For example, gold (Au) [Xe 4f145d106s1] is a noble metal with diverse uses and applications in society. From the discovery of the atomic nucleus to decorative jewelry, luxury goods and medicine, its conducting properties make it useful for many modern technological platforms including microelectronics, energy-harvesting, lighting and displays. Quantum confinement, on the other hand, can manipulate and generate exotic fundamental properties of low-dimensional materials, i.e. when the size of the materials is of the same magnitude as the de Broglie wavelength of the electron wave function. Nanostructured-Au, for instance, has different physical and chemical properties from bulk-Au. Besides being chemically active its optical and electrical responses to photons also change. Notably, there have been a lot of research efforts on using colloidal Au-nanoparticles for plasmonic sensors, electronics, and bio-medical applications due to their tunable optical properties with the emergence of surface plasmon resonance in the visible-range. However, all these nanoparticles were not pure gold, but instead required some complex polymer coating, and the plasmonic properties that were observed were conventional charge plasmons associated with oscillations of free electrons in the assembly of Au-nanoparticles. Another problem is the low reproducibility due to the complexity of the assembly Au nanoparticles, which make it difficult to control the conventional charge plasmons and their optical properties. As such, the existing methods for producing nano particles by synthesis of nanostructures including quantum dots (Au, transition metals, etc), nanoparticles; and self-assembly of the nanostructures including quantum dots, nanoparticles have limited the exploration of low-dimensional materials for various applications.

Embodiments of the present invention seek to address at least one of the above problems.

### SUMMARY

In accordance with a first aspect of the present invention, there is provided a method of fabricating low dimensional nanostructures on a growth substrate using physical vapor deposition, PVD, in a vacuum chamber wherein the low dimensional nanostructures are formed as a strain relief mechanism promoted by a similarity of crystal structure 2-dimensional symmetry between the growth substrate and the low dimensional nanostructures to be grown and a lattice mismatch between the growth substrate and the low dimensional nanostructures to be grown.

In accordance with a second aspect of the present invention, there is provided a single-crystalline low dimensional nanostructure exhibiting an electron-electron interaction based splitting in partial density of states of electron bands of the low dimensional nanostructures.

In accordance with a third aspect of the present invention, there is provided a device comprising one or more single-crystalline low dimensional nanostructures, wherein a response of the device is based on electron-electron interaction based splitting in partial density of states of electron bands of the low dimensional nanostructures.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1(a) shows a schematic drawing illustrating the method and according to an using a ultra-high-vacuum (UHV) molecular-beam-epitaxy (MBE) pulsed-laser-deposition (PLD) system with a base pressure of about 1×10⁻⁸ Torr.

FIG. 1(b) shows a schematic drawing illustrating low-dimensional nanostructure, e.g. quantum-dot, formation occurs on the substrate, according to an example embodiment.

FIG. 2 shows a fabrication process according to an example embodiment.

FIG. 3(a) shows an atomic force microscopy, AFM, image and sketch for growth without oxygen, according to an example embodiment.

FIG. 3(b) shows an AFM image and sketch for growth with oxygen, according to an example embodiment.

FIG. 4(a) shows an AFM image and sketch for growth on MgO(001), according to an example embodiment.

FIG. 4(b) shows an AFM image and sketch for growth on MgO(011), according to an example embodiment.

FIG. 4(c) shows an AFM image and sketch for growth on MgO(111), according to an example embodiment.

FIG. 5(a) shows a graph illustrating size control of Au QDs on MgO(001) through control of growth temperature, according to example embodiments.

FIG. 5(b) shows the AFM image surface morphology and graph of Au QDs grown on MgO(001) at 550° C. without O₂, according to an example embodiment.

FIG. 5(c) shows the AFM image surface morphology and graph of Au QDs grown on MgO(001) at 650° C. without O₂, according to an example embodiment.

FIG. 5(d) shows the AFM image surface morphology and graph of Au QDs grown on MgO(001) at 750° C. without O₂, according to an example embodiment.

FIG. 6(a) shows a sketch illustrating Au QDs form triangular or hexagonal shapes when fabricated on MgO(001) without oxygen, according to an example embodiment.

FIG. 6(b) shows a sketch illustrating Au QDs form triangular or hexagonal shapes when fabricated on MgO(111) without oxygen, according to an example embodiment.

FIG. 7(a) shows an AFM image and graph illustrating that when grown at 650° C. without oxygen, the crystal orientation is such that the Au(111) planes of the QDs are parallel to MgO(001), according to an example embodiment.

FIG. 7(b) shows an XRD illustrating the orientation of Au QDs with and without O₂ on MgO(001), according to example embodiments.

FIG. 7(c) shows an AFM image and graph illustrating that when grown at 650° C. with oxygen, the crystal orientation is such that the Au(111) planes of the QDs are parallel to MgO(001), according to an example embodiment.

FIG. 8(a) shows in-situ RHEED observations during growth of Au QDs, according to example embodiments.

FIG. 8(b) shows post-growth high-resolution synchrotron radiation X-ray diffraction (XRD) MgO-(002) rocking curve analyses of Au QDs, according to example embodiments.

FIG. 8(c) shows AFM images and graphs illustrating that higher growth temperatures on MgO(001) lead to the formation of smaller Au-QDs, according to example embodiments.

FIG. 8(d) shows in-situ XPS survey spectra of Au(111)-QDs grown at 650° C., according to an example embodiment.

FIG. 8(e) shows ex-situ XPS Au4f spectra of Au(111)-QDs grown at 650° C. according to an example embodiment.

FIG. 9 shows absorbance spectra of Au QDs according to example embodiments fabricated on MgO(001).

FIG. 10 shows XMCD results illustrating that the Au QDs fabricated according to an example embodiment are orbital-ordered and spin-polarized.

FIG. 11(a) shown comparative optical responses arising from the loss function, −Im[1/ε], including according to example embodiments.

FIG. 11(b) shows comparative ε₁ data of the complex dielectric function, ε≡ε₁+iε₂, including according to example embodiments.

FIG. 11(c) shows comparative ε₂ data of the complex dielectric function, ε≡ε₁+iε₂, including according to example embodiments.

FIG. 11(d) shows comparative reflectivity, R, data, including according to example embodiments.

FIG. 12 shows comparative spin-polarization bands in the XAS measurements, including according to example embodiment.

FIG. 13(a) shows the calculated LF according to example embodiments.

FIG. 13(b) shows the positive and high value of the calculated ε₁ accompanying the suppression low-energy Drude response, according to example embodiments.

FIG. 13(c) shows a calculated new Mott-like gap state is also captured in the calculated ε₂ with suppression low-energy Drude response, according to example embodiments.

FIG. 13(d) shows the calculated R according to example embodiments.

FIG. 13(e) shows a new proposed electronic structure of Au-QDs according to example embodiments.

FIG. 13(f) shows electromagnetic calculations based on Finite Difference Time Domain (FDTD) to calculate the optical reflectivity based on different quantum dot shapes and sizes of Au-QDs but without electronic correlations.

FIG. 13(g) shows electromagnetic calculations based on Finite Difference Time Domain (FDTD) to calculate the optical reflectivity based on different quantum dot shapes and sizes of Au-QDs but without electronic correlations.

FIG. 14(a) shows SERS signals, raw data, observed when 10 μM (1.8 ppm) of BPE dripped and dried on the Spin-SERS chip according to an example embodiment.

FIG. 14(b) shows SERS signals, background subtracted, observed when 10 μM (1.8 ppm) of BPE dripped and dried on the Spin-SERS chip according to an example embodiment.

FIG. 14(c) shows SERS signal observed using SERS-substrate of Au thin film with the same analyte, further signifying the unique role of the spin correlated-plasmon generated in Au-QDs according to example embodiments, and not in continuous Au thin film.

FIG. 14(d) shows SERS signal observed using SERS-substrate of quartz slide with the same analyte, further signifying the unique role of the spin correlated-plasmon generated in Au-QDs according to example embodiments, and not in continuous Au thin film.

FIG. 15(a) shows a schematic drawing illustrating a carrier substrate (e.g. Ge(001)) according to an example embodiment.

FIG. 15(b) shows a schematic drawing illustrating a thin layer of MgO is epitaxially deposited onto a carrier substrate (e.g. Ge(001)), according to an example embodiment.

FIG. 15(c) shows a schematic drawing illustrating a low dimensional nanostructure (e.g. Au QDs) are then deposited onto MgO according to an example embodiment.

FIG. 15(d) a schematic drawing illustrating a second substrate is bonded to the nanostructures from the top and MgO is removed (by dissolution) using deionized water, according to an example embodiment.

FIG. 15(e) shows a schematic drawing illustrating a complete transfer of the nanostructures to the second substrate, according to an example embodiment.

FIG. 16(a) shows the oscillator functions for thin Film Au.

FIG. 16(b) shows the oscillator functions for 650° C. Au(111)-QDs according to an example embodiment.

FIG. 16(c) shows the oscillator functions for 650° C. Au(001)-QDs according to an example embodiment.

FIG. 16(d) shows the oscillator functions for 750° C. Au(111)-QDs, according to an example embodiment.

### DETAILED DESCRIPTION

An example embodiment of the present invention provides a method for fabricating self-organized single-crystal low-dimensional nanostructures whose material comprises of one or more elements, including transition metals such as gold (Au), platinum (Pt), copper (Cu). Low dimensional nanostructures according to example embodiments include, but are not limited to, entities such as nanoparticles (NPs), quantum-dots (QDs), nano-dots (NDs), nanowires or nanolines (NWs or NLs). The fabrication method according to an example embodiment uses oxide-based substrates such as Magnesium-oxide (MgO), Strontium Titanate (SrTiO₃ or STO in short) as the starting surface for quantum-dot fabrication. Quantum-dots according to example embodiments may consist of pure element transition metals such as Au or Pt, or a combination of these elements forming binary, ternary or quarternary alloys. QDs fabricated according to example embodiments are single-crystalline and self-organized on the substrate surface such that the crystal-orientation of the QDs is tuneable and can be singly-directed. Additionally, the sizes and shapes of the QDs are tunable.

Low dimensional nanostructures according to example embodiments exhibit conventional and unconventional plasmons with properties not found in their bulk counterparts nor in similar nanostructures fabricated using existing methods. These plasmons are spin-polarized and are strongly-correlated. The self-organized single-crystal low dimensional nanostructures according to example embodiment exhibit unique properties at room-temperature such as magnetism (ferromagnetism) and are non-conducting. Such unique properties are also not found in their bulk counterparts nor in similar nanostructures fabricated using existing methods.

The fabrication method according to an example embodiment employs pulsed laser deposition (PLD) in ultra-high vacuum on targets consisting of the same material and composition as the quantum dots. The fabrication recipe according to an example embodiment is single-stepped and does not require post-treatment processes such as removal of residual reactants and precursors, or purification. The method according to an example embodiment does not require additional process such as Langmuir-Blodgett or nano-lithography to achieve self-assembly (self-organization). Due to its non-complex single-step process, the method according to an example embodiment is fast, highly reproducible and reliable. Low dimensional nanostructures according to example embodiment are 2D self-organized on a substrate surface and hence can immediately be used for several applications, including, but not limited to: (i) as a chip for surface enhanced Raman spectroscopy (SERS) and other plasmonic applications, (ii) as a chip for sensors utilizing its unique magnetic (spintronics) properties (iii) and optical properties, (iv) optoelectronic properties, (v) as a chip for biological applications such as bio-sensors, bio-tagging and bio-imaging, in applications for (vi) energy harvesting, (vii) catalyses, (viii) plasmonic lithography, and in (ix) quantum-computing.

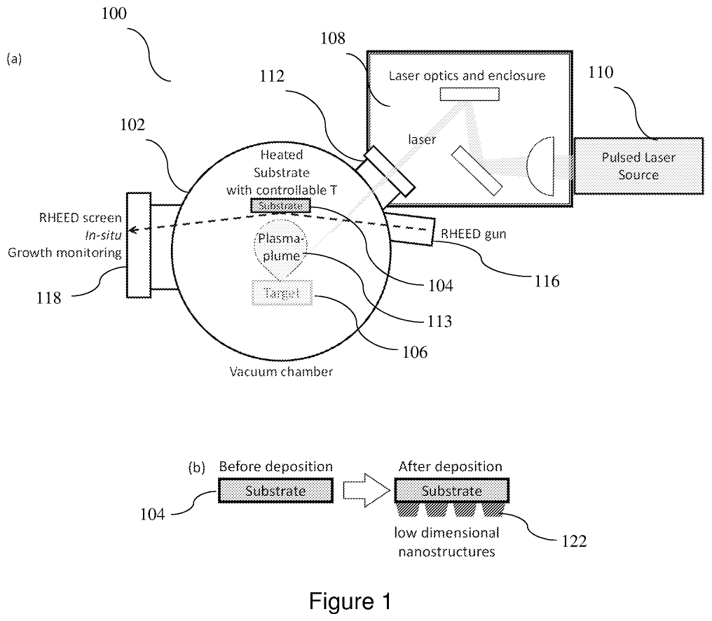

With reference to FIG. 1(a), the method according to an example embodiment uses a ultra-high-vacuum (UHV) molecular-beam-epitaxy (MBE) pulsed-laser-deposition (PLD) system 100 with a base pressure of about 1×10⁻⁸ Torr. A heated substrate holder with controllable temperate UHV chamber 102 is provided in a UHV chamber 102 for the substrate 104. A target holder is also provided in the UHV chamber 102 for the target 106. An enclosed laser optics 108 and pulsed laser source 110 are mounted on a chamber flange 112. the pulsed laser signal from the pulsed laser source 110 generates a plasma plume 113 from the target 106 for deposition onto the substrate 104. A RHEED gun 114 is and a RHEED screen 118 are provided for in-situ RHEED measurements during growth on the substrate 104. As illustrated schematically in FIG. 1(b) low-dimensional nanostructure, e.g. quantum-dot 122 formation occurs on the substrate 104.

One suitable example of a PLD system is Neocera PLD system with Continuum solid-state laser with 266 nm output wavelength and about 3.2 J/cm² laser power. It is noted, however that the method of fabrication according to example embodiments can also be carried out using systems other than PLD system, including vacuum-sputter systems, Molecular Beam Epitaxy systems and vacuum systems equipped with Electron-beam (E-beam) evaporators.

Prior to fabrication, the substrate 104 is loaded into the system without additional surface treatment (for example, no cleaning with isopropanol was applied) and is annealed (for example, 900° C. for MgO(001) substrate or 850° C. for STO(001) substrate) for a period of time up to 60 minutes. The substrate 104 is then brought to the desired substrate temperature prior to nanostructure fabrication. The target 106 used for nanostructure fabrication is first cleaned by pulsed-laser ablation (up to 1000 pulses at 10 Hz). Accidental deposition onto the substrate is avoided using a shutter that covers the sample during pulsed-laser ablation. Oxygen overpressure (oxygen feeding system not shown in FIG. 1(a)) is then enabled in the system where both substrate 104 and target 106 are exposed to a fixed amount of oxygen during fabrication. Low dimensional nanostructures such as QDs are then formed on the substrate 104 via pulsed-laser deposition (PLD) using a desired number of laser pulses and laser frequency (in Hz), which allows tuning of nanostructure size based on the substrate temperature, number of laser pulses and laser frequency, and oxygen overpressure, as will be described in detail below.

### Substrates for Use According to Example Embodiments

The substrates on which the low dimensional nanostructures are formed according to example embodiments include, but not limited to, the following: semiconductor (Si, Ge, Sn), oxides (MgO, TiO₂, SrTiO₃, LaAlO₃). Criteria for the choice of substrate are based on the symmetry-matching and lattice-matching between the substrate surface and the nanostructures. For instance, to obtain square-shaped Au QDs, lattice-matched substrates such as MgO is preferred as the lattice-mismatch and registry between Au and MgO is small (˜−3.2%). In one example embodiment, MgO(001) is the substrate choice (as opposed to MgO with other surface orientations such as MgO(111)) as the substrate surface has a square symmetry that acts as a surface template for the formation of square-shaped Au QDs. Other choices of substrates include off-cuts (vicinal) and pre-patterned substrates which allows templated growth of QDs according to example embodiments.

### Targets for Use According to Example Embodiments

Targets are the growth material which are used in PLD to grow low dimensional nanostructures according to example embodiments. The composition and stoichiometry of the target should match that of the nanostructures. For instance, to obtain Au QDs, high-purity (>99.9% purity) Au target is used in an example embodiment. Due to the small laser-spot used in PLD growth, the size of the target is typically small (1-inch in diameter).

### Controllable Growth Rate According to Example Embodiments

In pulsed laser deposition (PLD) growth, a small laser is used to ablate the target during growth. During this process, material from the target that is being ablated is deposited onto a heated substrate, thereby forming QDs on the substrate. The rate at which the material falls onto the substrate depends mainly on the laser power and laser pulse frequency. This in turn allows a highly reproducible, controllable growth rate for the fabrication of the QDs.

Fabrication of low dimensional nanostructures using the method according to an example embodiment resolves two main challenges with existing synthesis of Au NPs via chemicals.

Use of precursor chemicals are commonplace in conventional low dimensional nanostructure (such as QDs and NPs) fabrication methods such as chemical synthesis. These conventional methods usually leave residual chemicals (by-products) that need to be removed through purification, which is time-consuming. Furthermore, QDs (NPs) fabricated via these conventional methods are predominantly in solution form. To prevent instability and aggregation of these nanostructures which leads to degradation, additional chemicals are often added to the synthesis process to protect these nanostructures and prevent aggregation by encapsulating them with surfactants. Excess or residual surfactants and by-products need to be further removed by purification in the post-processing. Furthermore, the use of surfactants changes the properties (physical, chemical, electrical, etc) of the nanostructures. Low dimensional nanostructures fabricated using the method according to an example embodiment avoids the use of precursor chemicals and surfactants entirely. The nanostructures according to example embodiments do not require post-fabrication treatment to remove residual precursor chemicals and do not require further time-consuming purification process.

Low dimensional nanostructure fabricated using the method according to an example embodiment are already organized (assembled) in the form of a 2-dimensional array/layer on a substrate and is therefore suitable for immediate applications such as surface enhanced Raman spectroscopy (SERS) or as 2D chemical or biological sensors. The method according to an example embodiment does not require additional time-consuming steps to assemble the QDs together in existing techniques using methods such as the Langmuir-Blodgett or the Langmuir-Schaefer techniques, or through the use of nano-patterning masks or lithography. By avoiding this additional step of assembly, the method according to an example embodiment prevents further contaminations from additional chemicals that may be used in the self-assembly process. In addition, the QDs according to an example embodiment are self-organized during the fabrication step in a vacuum system and hence can be easily integrated into technological platforms for device fabrication.

### Example Embodiments: Au Quantum Dots (QDs) Fabricated on MgO Substrates

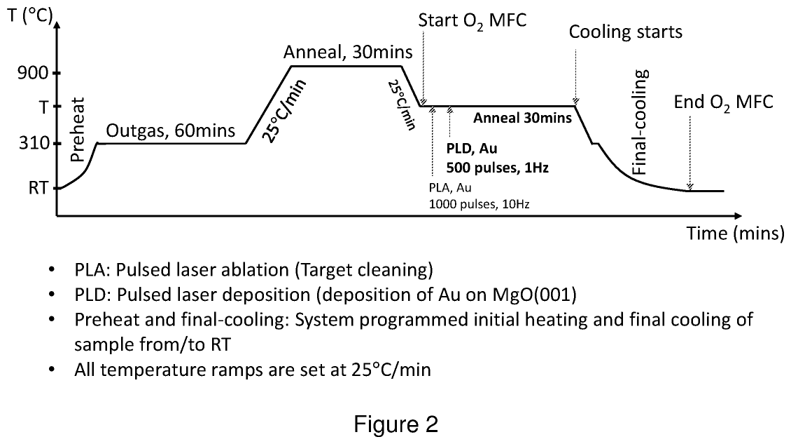

In one example embodiment of low dimensional nanostructure fabrication, single-crystalline self-organized Au QDs are fabricated on MgO substrates. The shape and sizes of Au QDs according to an example embodiment are tuned according to the substrate temperature (between 300° C. and 800° C.), number of laser pulses and oxygen overpressure ranging from 0 mTorr (no oxygen) to 100 mTorr. FIG. 2 shows a fabrication process according to an example embodiment, illustrated as a plot of substrate temperature (° C.) vs time (mins) as well as deposition start and end procedures, for Au QDs. The entire process takes about 3 hours or less according to an example embodiment. Generally, it was found that between 300° C. and 800° C., QDs formed are single-crystalline. At room temperature, pulsed laser deposition of Au leads to polycrystalline Au.

The following details the results based on Au QDs fabricated on MgO substrates, according to example embodiments.

The Au QDs fabricated according to example embodiments are predominantly single-crystalline and are self-organized (also termed self-assembled), i.e. the QDs crystal orientation are dominated by one crystal direction such as (001)/MgO(001) with cubic symmetry or (111)/MgO(001) with hexagonal/triangular symmetry.

The shape, size and orientation of Au QDs according to example embodiments can be controlled by changing substrate temperature, oxygen overpressure and/or MgO substrate type (i.e. MgO(001), MgO(111) and MgO(110)):

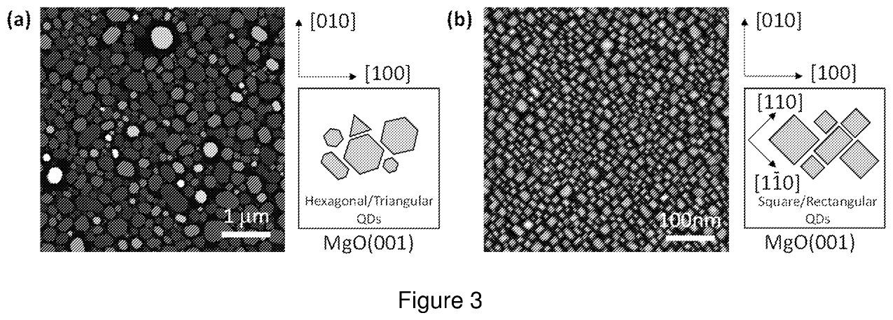

The shape and orientation of the QDs can be controlled by controlling the flow of oxygen into the PLD chamber during growth. Without oxygen, the QDs are hexagonal and/or triangular in shape (see atomic force microscopy, AFM, image and sketch in FIG. 3a). When O₂ overpressure is introduced, the QDs shape changes to square and/or rectangular shapes and they are aligned along <110> directions of the MgO(001) substrate (see AFM image and sketch in FIG. 3b).

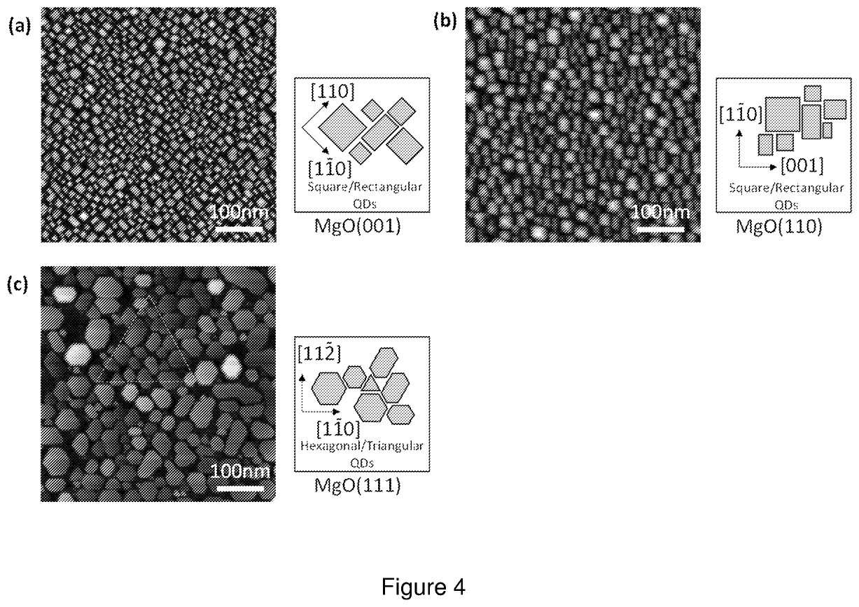

The shape and orientation of the QDs can also be controlled using substrates with different surface symmetries. On surfaces with square symmetries such as MgO(001) and MgO(110), the Au QDs follows the symmetry forming QDs with square and rectangular shapes (see AFM images and sketches in FIGS. 4a and 4b), whereas on triangular symmetries such as MgO(111), these QDs take the form of hexagonal or triangular shapes (AFM image and sketch in FIG. 4c).

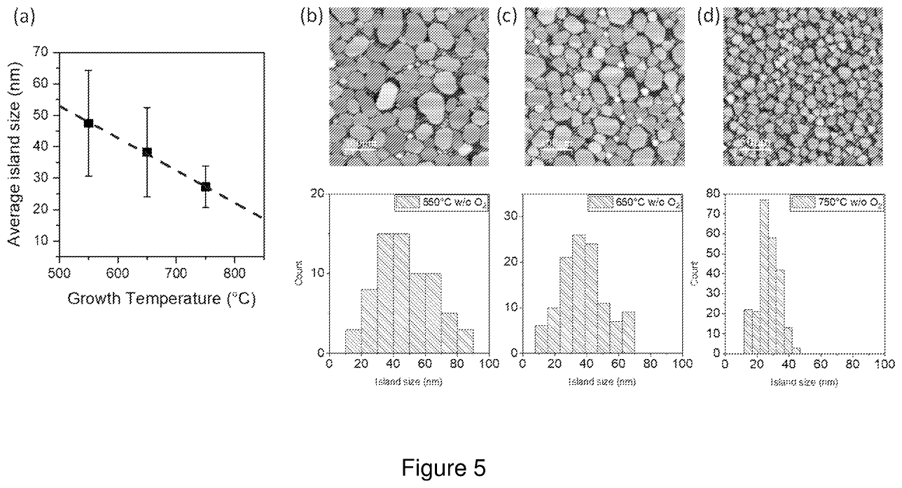

Size control of Au QDs on MgO(001) through control of growth temperature according to example embodiments is illustrated in the graph in FIG. 5(a). FIG. 5(b-d) shows the AFM image surface morphologies of Au QDs grown on MgO(001) at 550° C., 650° C. and 750° C. without O₂. The size of the Au QDs are also shown in the size distribution plots at the bottom in FIGS. 5(b-d). With increasing growth temperature, the QDs size decreases from 47.5±16.8 nm (450° C.) to 38.2±14.2 nm (550° C.) and 27.2±6.6 nm (750° C.), according to example embodiment. The QD-size and size distribution of the Au QDs become smaller and narrower by increasing the growth temperature, according to example embodiments.

Au QDs grown according to example embodiments also allows the control of Au crystal orientation with respect to the MgO substrate surface. Conventionally, the control of crystal orientation of Au QDs is difficult and requires further processing steps such as the Langmuir-Blodgett technique to enable self-assembly of the QDs. Even so, the nature of the QDs, which are conventionally fabricated chemically, are polycrystalline at best. Advantageously, the fabrication method according to an example embodiment allows not only the fabrication of single-crystalline Au QDs (as described below), and their crystal orientation can also be controlled to singly orientate in one direction with respect to the MgO substrate surface.

### Lateral Crystal Orientation Control—Template Effect Using Symmetry of the Substrate

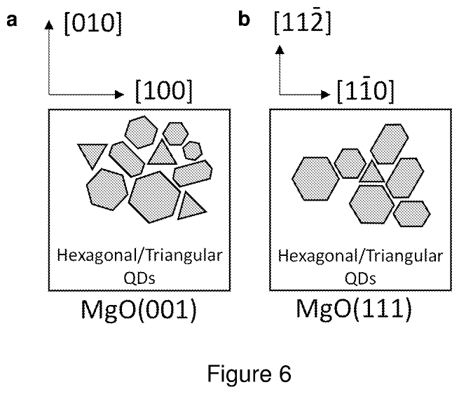

Au QDs form triangular or hexagonal shapes when fabricated on MgO(001) without oxygen, according to an example embodiment. The lateral orientation of the QDs appear to be random (see FIG. 6a and FIG. 3a). These QDs can be aligned in the same lateral direction by using MgO(111) substrate (see FIG. 6b and FIG. 4c), according to an example embodiment.

### Control of Au QDs Crystal Orientation Through Oxygen Overpressure Control

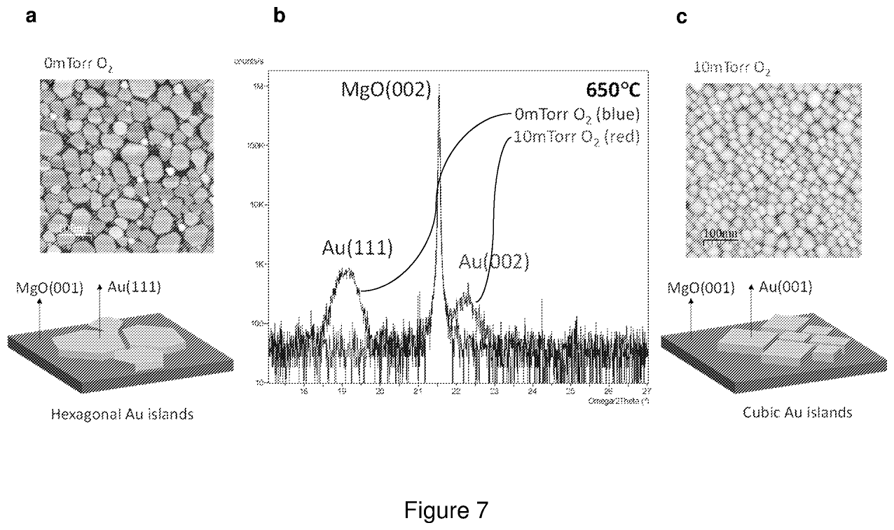

Room temperature growth with or without O₂ resulted in bulk-like Au polycrystalline thin film. However, when grown above 300° C., Au QDs form triangular or hexagonal shapes when fabricated on MgO(001) without oxygen, according to an example embodiment. When grown at 650° C., the crystal orientation is such that the Au(111) planes of the QDs are parallel to MgO(001) (see FIG. 7(a)). In other words, the Au QDs form on the substrate are single-crystalline with their (111) planes parallel to MgO(001) surface, according to an example embodiment. With the addition of oxygen overpressure at the same growth temperature of 650° C., the crystal orientation changes such that the Au(001) planes of these QDs are parallel to MgO(001) instead. These QDs are single-crystalline with their (001) planes parallel to the MgO(001) surface, according to an example embodiment, see FIG. 7(c). XRD plot (FIG. 7(b)) shows the orientation of Au QDs with and without O₂, according to example embodiments. Without O₂, the QDs are aligned with Au(111)/MgO(001). With O₂, the QDs are aligned with Au(001)/MgO(001). The Au(002) XRD peak indicates the QD orientation where Au(001)/MgO(001).

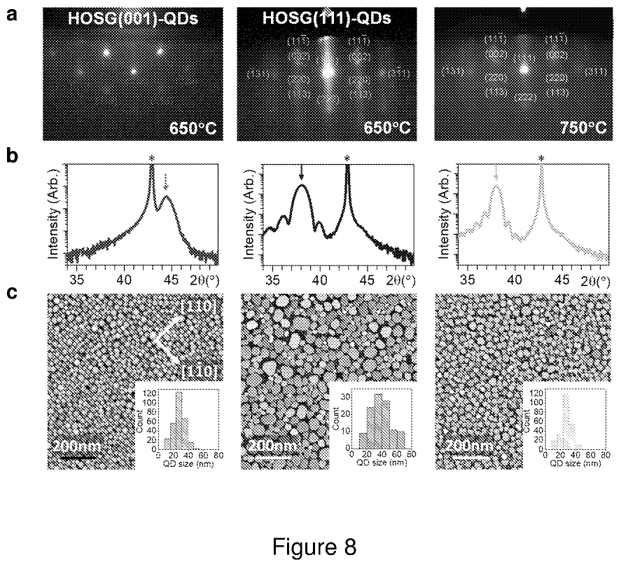

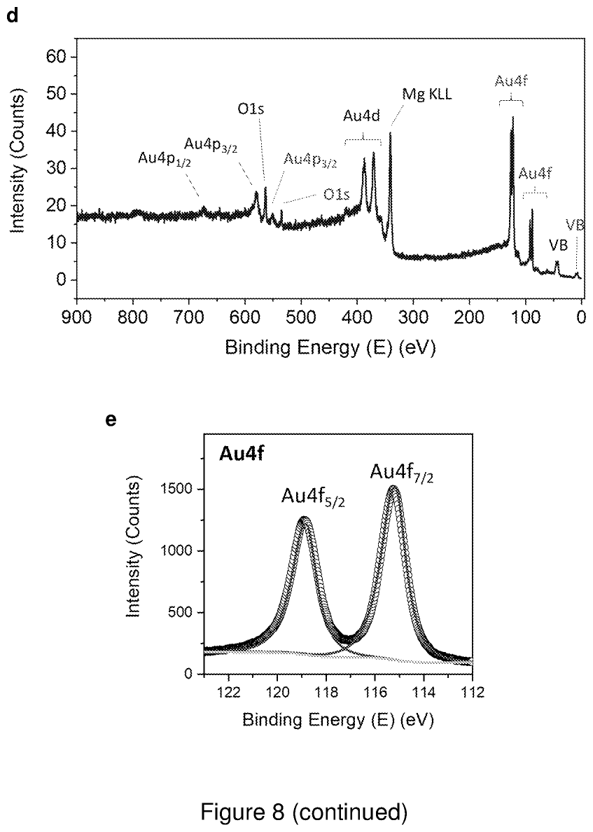

In UHV-MBE-PLD of Au on MgO(001) according to example embodiments above 300° C. in-situ RHEED observations (see FIG. 8(a)), together with post-growth high-resolution synchrotron radiation X-ray diffraction (XRD) MgO-(002) rocking curve analyses (see FIG. 8(b)) also reveal a Volmer-Weber epitaxial growth-mode. The two types of Au-QDs structures according to example embodiment are found to be self-organized on the MgO(001) substrate. Again, growth in the presence of O₂ leads to preferential and selective formation of square-shaped Au(001)-QDs with face-centered cubic Au (001) planes parallel to the MgO(001) substrate. Contrastingly, growth without O2 results in the formation of hexagonal- and triangular-shaped Au(111)-QDs decorating the MgO(001) surface with low surface energy Au (111) planes parallel to the MgO(001) substrate, according to an example embodiment. By growing in an oxygen-rich regime, the cubic-on-cubic growth of square-shaped AU-QDs on MgO(001) surface is promoted according to an example embodiment by preserving the surface registry of the idealized MgO(001) square unit-cell with little or no oxygen vacancies for the stronger Au—O binding. Higher growth temperatures lead to the formation of smaller Au-QDs (see FIG. 8(c)) according to example embodiments.

In-situ XPS survey spectra of Au(111)-QDs grown at 650° C. according to an example embodiment are shown in FIG. 8(d). Au peaks 901-905 pertain to Au(111)-QDs on MgO(001) according to an example embodiment, which are charged to higher binding energies (BE) by ˜38.3 eV. Au peaks 911-914 belong to XPS signals from the sample holder which is conducting and are therefore not charged. The Mg KL₂₃L₂₃ Auger signal and O1s peak are attributed to the MgO substrate.

Ex-situ XPS Au4f spectra of Au(111)-QDs grown at 650° C. according to an example embodiment are shown in FIG. 8(e). The Au4f doublets which are charged to higher BE by 31 eV appear to be unoxidized.

Formation of self-organized Au-QDs and Au thin films can thus be templated on a MgO(001) surface in the one-step fabrication process according to an example embodiment. The fabrication process according to an example embodiment hence avoids the need for multi-step processes and complexity of solution-based methods typically established for the synthesis of colloidal Au-NPs, often involving capping with surfactants for stabilization, and subsequently performing the Langmuir-Blodgett technique for self-assembly on substrates. The UHV-MBE-PLD according to an example embodiment provides a direct and real-time control and the ability to tune the crystallinity, phase, size and structure of e.g. Au QDs (i.e. either the preferential formation of (111)-QDs or (001)-QDs, and/or the co-existence of both types epitaxially on the MgO(001) surface This is important as it allows for the first time, to the inventors' knowledge, the optical response, quantitatively and qualitatively, from the Au-QDs according to example embodiments to be studied unambiguously using advanced spectroscopic ellipsometry, which is sensitive to spin and charge excitations. Together with XAS, XMCD, Electron and X-ray diffractions, direct measurements of spin, charge, orbital and lattice of Au on MgO can thus be ascertained to provide insights into its fundamental spin and electronic interactions with photons, either as a regular noble metal and/or as a strongly correlated electron system according to example embodiments.

### Properties Possessed by Au QDs Fabricated on MgO Substrates According to Example Embodiments

### Colors of Au QDs According to Example Embodiments

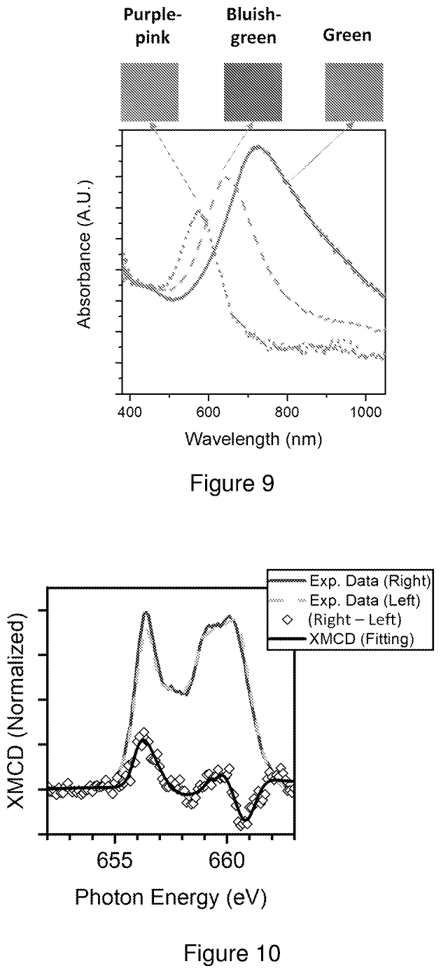

The Au QDs according to example embodiments exhibit colors based on their sizes, shapes and oxidation states. In one example application, the nanostructures according to example embodiments can be used for surface enhanced Raman scattering (SERS) where they exhibit selective responses (based on their sizes) when lasers of different wavelengths are used (see FIG. 9, noting that FIG. 9 shows the absorbance spectra of Au QDs according to example embodiments which can be tuned to possess different absorbance wavelengths. The samples in FIG. 9 according to example embodiments were fabricated on MgO substrates at 450° C. under different O₂ pressures: Purple-Pink—100 mTorr O₂, Bluish-green—10 mTorr O₂, and Green—0 mTorr O₂ (i.e. no O₂).

Due to the different absorbance wavelengths, the Au QDs according to example embodiments will also show different responses in SERS when SERS is run using lasers with different wavelengths. For instance, no SERS signal is obtained for purple-pink Au QDs when 785 nm laser is used but strong signal is obtained when 532 nm laser is used. The colors of Au QDs according to example embodiments fabricated on MgO(001) are illustrated by absorbance of different wavelengths (Purple-pink: 575 nm, Bluish-green: 642 nm and Green: 725 nm). These low-dimensional nanostructures generate specific responses from lasers with different wavelength (532 nm, 633 nm and 785 nm) in surface-enhanced Raman scattering (SERS).

### Significant Enhancement in the Spin and Orbital Polarization of Au QDs According to Example Embodiments

XMCD results (see FIG. 10) show that the Au QDs fabricated according to an example embodiment are orbital-ordered and spin-polarized. These unique properties have not been observed on uncapped Au QDs (or nanoparticles) previously reported. The QDs according to an example embodiment therefore exhibit magnetic properties such as ferromagnetism useful for bio-applications without the need to incorporate magnetic materials such as Fe or Ni that are bio-incompatible. The plots in FIG. 10 show the responses of the sample when it is probed using left-circular polarized photons (“Left”) and right-circular polarized photons (“Right”). For materials without spin-polarization properties, there is no difference in the response between Left or Right Circular Polarization. On the other hand, for materials that are spin-polarized, there is a difference in the response between left or right circular polarization. This difference can be made clearer when one of the spectra is subtracted by the other (“Right-Left”).

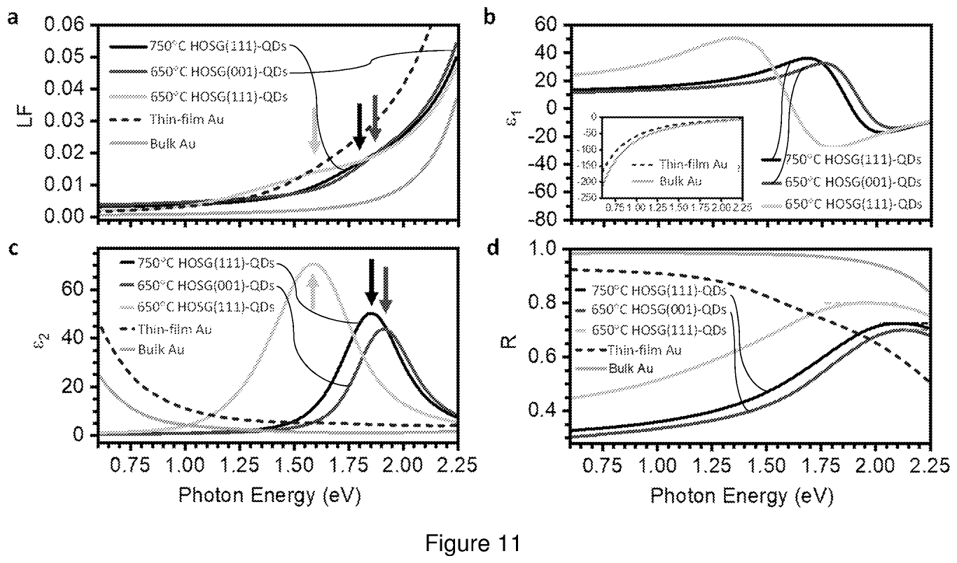

Au thin film exhibits characteristics of a metallic conducting film (grown at room temperature but otherwise using the same UHV-MBE-PLD system as for Au QDs according to example embodiments) akin to bulk Au, as shown in the optical response arising from the loss function, −Im[1/ε] (see FIG. 11(a)), which is the most direct way to measure plasmon response, complex dielectric function, E≡ε₁+iε₂ (see FIG. 11(b) and FIG. 11(c)), and reflectivity, R (see FIG. 11(d)). For photon energies less than 1 eV, ε₁ shows a very high negative value, as is typical of Au bulk, suggesting that the low energy electrons are screened (inset of FIG. 11(b)), while ε₂ shows the typical Drude response for Au as a metal arising from the electronic intra-band transitions dominated by free-electron behavior in the partially filled sp bands, which cross the Fermi-level (FIG. 11(c)). For photon energies of ˜1 to ˜2 eV, ε₂ is suppressed and ε₁ approaches finite values but remains negative. The loss function for Au thin films and Au bulk exhibits an associated absorption tail of inter-band contributions (5d→6sp), which extends to about 1.8 eV (see FIG. 11(a)).

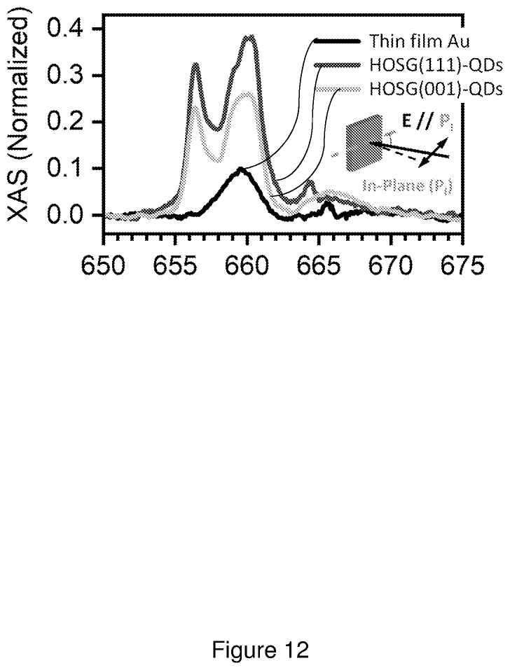

The main observation is that Au QDs according to example embodiments remarkably show a vastly different optical response compared to Au thin films and Au bulk. The loss function now has new peaks at about 1.54 eV, 1.88 eV and 1.82 eV for 650° C. Au(111)-QDs, 650° C. Au(001)-QDs and 750° C. Au(111)-QDs, respectively (FIG. 11(a)). Through a thoroughly and comprehensive analysis supported with detailed theoretical calculations (as will be described below), these peaks are attributed to the presence of a new exotic unconventional plasmon, namely spin correlated-plasmon, arising from surprisingly strong spin-polarization s band of Au-QDs self-organized on MgO(001), according to an example embodiment. The new peaks are distinctively missing from the optical response for the Au thin film and bulk Au. For photon energies less than 1 eV, interestingly, ε₁ turns positive (FIG. 11(b)) for the Au-QDs according to example embodiments, revealing that electrons are unusually unscreened. More significantly, ε₂ shows spectral weight transfer in a broad energy range, i.e. a dramatic suppression of the low-energy Drude response accompanied by an occurrence of an anomalous quantum absorption of a midgap state at ˜1.58 eV, ˜1.90 eV and ˜1.86 eV for 650° C. Au(111)-QDs, 650° C. Au(001)-QDs and 750° C. Au(111)-QDs according to example embodiments, respectively (FIG. 11(c)). The quantum absorption occurs due to unusually strong spin-polarization in Au-6s and hybridizations of Au-6sp with 5d bands and its energy determining the strength of the spin-splitting. The intensity of ε₂ of quantum absorption is enormous, which is as high as ˜70. While ε₁ is unusually high approaching ˜50. This spectral weight transfer is a fingerprint of strong electronic correlations, responsible for generating metal to Mott-like insulator transition and transparency and yielding the new spin correlated-plasmon observed in the loss function of Au-QDs according to example embodiments (FIG. 12). The energy of spectral weight transfer observed in Au-QDs according to example embodiments is surprisingly large, i.e. at least ˜1.58 eV, a magnitude that is comparable to the strong electron-electron correlations in the charge transfer (O2p-Cu3d) of copper oxide-based high-temperature superconductors (cuprates) and in d-d Mott-transition of manganites as revealed by high-energy optical conductivity measurements. This is unusual because electrons in s band are well-screened and non-correlated as shown in the bulk Au as well as Au thin film. Such strong electron-electron correlations in s band of Au-QDs according to example embodiment create a Mott-like gap, which is comparable to the direct bandgap of semiconductors such as GaAs whose E_{g} is about 1.4 eV. The peak position is found to shift to higher energies as the QD size decreases. The differences in optical response are also revealed in the reflectivity plots of FIG. 11(d), where a significant decrease in reflectivity around photon energies of 1.9 eV and 2.0 eV occurs for Au-QDs according to example embodiments but not for bulk-like thin film.

These unusual optical responses, attributed to the presence of the spin correlated-plasmon in Au-QDs according to example embodiments are due to spin-polarization bands as proven in the XAS and XMCD measurements (FIG. 12 and FIG. 10, respectively) supported with theoretical calculations (described below). Particularly, it was found that the degeneracy of the 6s bands at the Fermi-level is lifted and split to form a gap between the spin-up and spin-down states. Indeed, XAS measurements at room temperature (FIG. 12) show unequivocally the existence of a new Au 6s+5d hybridization state yielding Au 4p→6s+5d transition at ˜656 eV, which is absent in the Au bulk thin film. For the bulk-like Au thin film, only a broad hump at ˜660 eV attributed to the Au 4p→6sp transition is observed. For the Au-QDs according to example embodiments, intriguingly, a new sharp peak at ˜656 eV is observed, while the peak at ˜660 eV becomes enhanced and well-resolved into multiple peaks (FIG. 12). This new sharp peak at ˜656 eV is attributed to the interplay between electron-electron interactions, quantum confinement due to size and orientation and Au-6s hybridized with 5d through the O2p state arising from the self-assembly of Au-QDs on MgO(001) according to example embodiments yielding to spin-polarized bands as supported by previous density functional theory calculations.

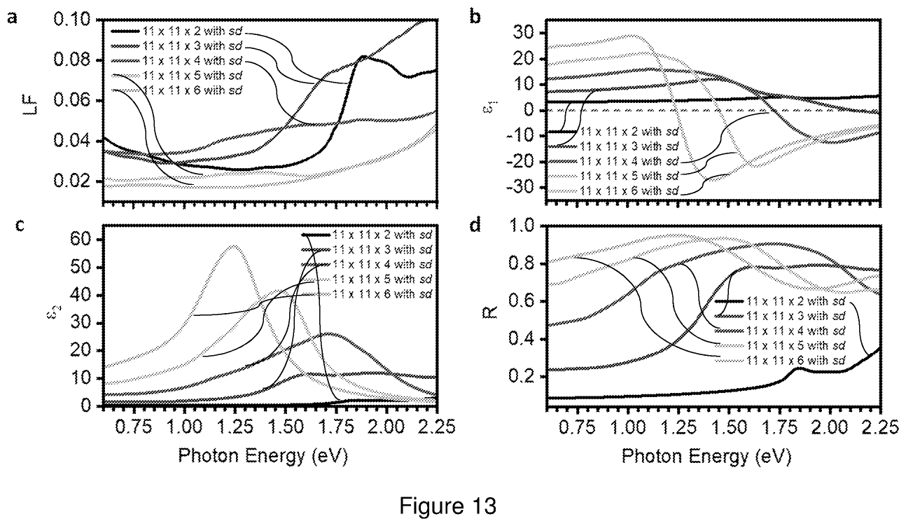

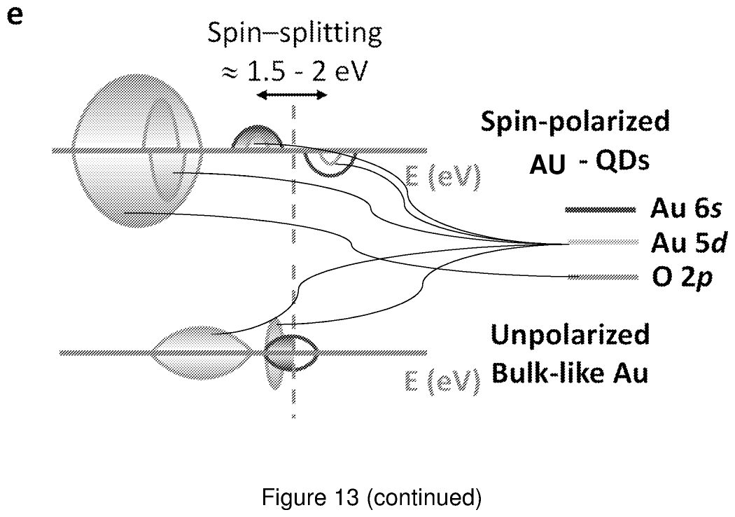

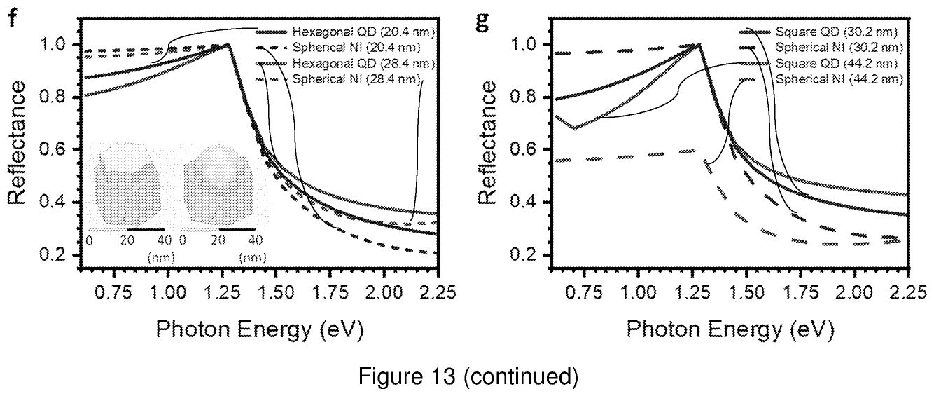

As mentioned above, the experimental observations are supported by theoretical calculations. Using a tight-binding model incorporating s-d hybridizations and on-site Hubbard repulsion treated within mean field approximation, theoretical calculations show that the occurrence of the unconventional spin correlated-plasmon is due to the existence of strong electronic correlations; in this case, the s-d hybridization and hopping electrons due to the finite sizes of Au-QDs formation on MgO(001) according to example embodiments (as will be described in more detail below). The presence of s-d hybridization creates splitting in the partial density of states for both s and d bands (FIG. 13). The calculated out-of-plane optical responses of LF, ε₁, ε₂, and reflectivity R (see FIG. 13) agree well with the experimental results (FIG. 11). The calculated LF (FIG. 13(a)) indeed shows spin correlated-plasmon in the visible accompanied by positive value of ε₁. A new Mott-like gap state is also captured in the calculated ε₂ (FIG. 13(c)), as well as suppression low-energy Drude response, accompanied with positive and high value of the calculated ε₁ (FIG. 13(b)). From the theoretical calculations, it is also inferred that the optical response data have a dominant contribution from the out-of-plane responses. Combining both experimental data and the theoretical calculations, a new electronic structure of Au-QDs according to example embodiments is proposed (see FIG. 13(e)). It is found that an interplay of electron-electron correlations, s-d hybridization and quantum confinement in the Au-QDs according to example embodiments plays an important role in the generation of the spin correlated-plasmon in the loss function, a quantum absorption Mott-like state and disappearance of low-energy Drude response in complex dielectric functions. Such an interplay changes Au-6s degenerate state to a split spin-polarized state with an energy difference of about 1.5 eV-2 eV between the split states (FIGS. 13(b) and (e)) as identified by the quantum absorption (FIG. 11(c)).

For comparison, electromagnetic calculations based on Finite Difference Time Domain (FDTD) were also performed and calculate the optical reflectivity based on different quantum dot shapes and sizes of Au-QDs but without electronic correlations (FIGS. 13(f) and (g)). It was found that the quantum confinement due to the shapes and sizes alone cannot explain the experimental results (FIG. 11(d)). This further supports that electronic correlations are enhanced and play and important role in the quantum confinement of Au-QDs according to example embodiments.

More specifically, the optical responses FIG. 13(a)-(d) show the effect of thickness variation on the out-of-plane optical responses with s-d hybridization, V_{s-d}=1 eV, for Au systems with size 11×11×N atoms (where N=2, 3, 4, 5 or 6). FIG. 13(e) shows schematic band energy diagrams depicting the spin-polarized, spin-splitting and hybridization of 6s-5d density-of-states near the Fermi-level for Au-QDs according to an example embodiment, in contrast to unpolarized bulk-like Au. FIG. 13(f) shows Finite Difference Time Domain (FDTD) electromagnetic simulation results showing calculated reflectivity from an infinite array of hexagonal-shaped quantum dots (QD) and partially-embedded spherical nano-islands (NI). The diameter is set at 20.4 nm and 28.4 nm. Both systems are arranged in a hexagonal array with a spacing of 7 nm between the QD or NI. Inset: Geometries of a single hexagonal QD and a single spherical NI. In FIG. 13(g), the FDTD simulation shows the calculated reflectivity from an infinite array of square-shaped QD and partially-embedded spherical NI. The diameter is set at 30.2 nm and 44.2 nm. Both systems are arranged in a square array with a spacing of 7 nm between the QD or NI. The simulations are run with QD (or NI) sizes in the same range as the hexagonal-shaped Au-QDs and square-shaped Au-QDs according to example embodiments shown in FIG. 8.

### Theoretical Modelling of Au on MgO According to an Example Embodiment

The modelling and calculations, within tight-binding scheme in site representation incorporating s-d hybridization and on-site Hubbard repulsion treated within mean-field approximation, are described in the following to explain the experimental data.

### Model Atomic Positions

An Au nanoparticle is modeled as consisting of Au atoms forming face-centered cubic (fcc) structure with primitive lattice vectors a₁, a₂, and a₃, such that the position of each i^{th} atom can be described as

Rᵢ=la₁+ma₂+na₃. (2)

The atomic positions are taken such that M×M atoms form a plane of equilateral parallelogram shape for which a₁ and a₂ are the basis vectors. The whole nanoparticle system of size M×M×N is then formed by the stacking of N such equilateral parallelograms where each two adjacent planes are separated by the 3rd primitive lattice vector a₃. M is set to be always bigger than N.

### Model Hamiltonian

The Au atom has electronic configuration of [Xe] 4f¹⁴ 5d¹⁰ 6s¹. When the atoms form a crystal, the Fermi level falls in the 6s orbital, while all the other orbitals are fully occupied. This determines that the dynamics of the electrons observed through the optical response in the first few eVs mostly originate from this 6s orbital. The closest lower energy orbitals are the 5d orbitals. To simplify our model, we take only this 6s orbital and one of the five d orbitals in our basis set. Thus, taking spin into account, overall we have (1+1)×2=4 basis states per atom. With these basis states, a Hamiltonian of the form so-called Periodic Anderson Model (PAM) is formed as the following:

$$H = {ϵ}_{s} {\sum }_{i} {s}_{i σ}^{†} {s}_{i σ} + {ϵ}_{d} {\sum }_{i} {d}_{i σ}^{†} {d}_{i σ} - t {\sum }_{〈 ij 〉 σ} {s}_{i σ}^{†} {s}_{i σ} + V {\sum }_{i σ} ( {s}_{i σ}^{†} {d}_{i σ} + {d}_{i σ}^{†} {s}_{i σ} ) + U {\sum }_{i} {n}_{di ↑} {n}_{di ↓} \qquad ( 3 )$$

In Eq. (3) s_{iσ}^{†} and s_{iσ} are the creation and annihilation operators for the s orbital with spin σ at site i, respectively, likewise d_{iσ}^{†} and d_{iσ} are the creation and annihilation operators for the d orbital with spin σ at site-i, respectively, and n_{di↑(↓)}=d^{†}_{i↑(↓)} d_{i↑(↓)} is the d-orbital occupation number operator for spin ↑ (↓) at site i. ∈ₛ and ∈_{d} are the on-site energies of the s and d orbitals, respectively; t is the hopping parameter connecting the s orbitals within nearest neighbor, where [symbol] ij [symbol] i signifies that the summation is over all nearest neighbor pairs; V is the s-d hybridization coupling; and U is the on-site Hubbard repulsion of the d orbital. As the d orbital is full and the s orbital is partially occupied, then the electron filling in our model is 2+1=3 electrons per atom.

### Mean-Field Theory

The on-site Hubbard term makes the exact solution to this model become practically impossible. A rigorous treatment on this term would require a sophisticated computational method. It was chosen to take the mean-field theory (MFT) to handle the on-site Hubbard repulsion term with the approximation

n_{di↑}n_{di↓}≈ [symbol] n_{di↑} [symbol] n_{di↓}+n_{di↑} [symbol] n_{di↓} [symbol] − [symbol] n_{di↑} [symbol] [symbol] n_{di↓} [symbol] (4)

### Self-consistency with MFT

Computationally, the model is solved by means of Green function technique. First, the s orbitals for the up-spin are labelled with indices 1, 2, . . . to Nₛᵢₜₑₛ; the d orbitals for the up-spin with indices Nₛᵢₜₑₛ+1, Nₛᵢₜₑₛ+2, . . . , 2Nₛᵢₜₑₛ; the s orbitals for the down-spin with indices 2Nₛᵢₜₑₛ+1, 2Nₛᵢₜₑₛ+2, . . . , 3Nₛᵢₜₑₛ; and the d orbitals for the down-spin with indices 3Nₛᵢₜₑₛ+1, 3Nₛᵢₜₑₛ+2, . . . , 4Nₛᵢₜₑₛ, where Nₛᵢₜₑₛ=M×M×N. With this representation the non-perturbed part of the Hamiltonian (the first and the second terms of Eq. (3)) are constructed in a (4Nₛᵢₜₑₛ)×(4Nₛᵢₜₑₛ) matrix form [H₀]. The Hubbard interaction term, which is treated within MFT, is absorbed into a self-energy matrix [Σ_{MF}], whose elements are non-zero only in the diagonal parts in the form of U [symbol] n_{di↑(↓)} [symbol] . Here, the average d orbital occupation number [symbol] n_{di↑(↓)} [symbol] is to be computed self-consistently starting with a set of initial guess values along with the initial guess for the chemical potential μ.

Next, the corresponding “retarded” Green function matrix is constructed as

[G(ω)]=[(ω+iη)[I]−[H₀]−[Σ_{MF}]]⁻¹ (5)

The projected density of states for each corresponding orbital index α from the diagonal elements of [G(ω)] is computed as

$${PDOS}_{α} ( ω ) = - \frac{1}{π} Im {G}_{α α} ( ω ) \qquad ( 6 )$$

and the total density of states as

$$D 0 S ( ω ) = {\sum }_{α} P D 0 {S}_{α} ( ω ) \qquad ( 7 )$$

The DOS is then used to update the chemical potential μ by imposing the electron filling constraint

∫dωDOS(ω)f(ω,μ,T)=n_{filling}=3, (8)

where f(ω,μ,T) is the Fermi-Dirac distribution function. The updated chemical potential value is used to compute the new average occupation number of each orbital labeled α as

[symbol]

n_{α} [symbol] =∫dωPDOS_{α}(ω)f(ω,μ,T) (9)

These average occupation numbers also include [symbol] n_{di↑(↓)} [symbol] for d orbitals that are to be used to update the mean-field self-energy matrix [Σ_{MF}]. This process is iterated self-consistently until the set of [symbol] n_{di↑(↓)} [symbol] values or the [Σ_{MF}] is converged.

### Optical Conductivity

Self-consistent “retarded” Green function matrix [G(ω)] is used to compute the optical quantities. As a start, the real part of the complex optical conductivity tensor σ_{1γλ}(ω) is computed, where γ and λ are the pair of indices corresponding to the directions of the incoming photon electric field vector and the measured outgoing one, that is

$$( 10 )$$

$${σ}_{1 γ λ} ( ω ) = \frac{π {e}^{2}}{ℏ a} \int dv ( \frac{f ( v , μ , T ) - f ( v + ω , μ , T )}{ω} ) Tr [ {v}_{γ} ] [ A ( v ) ] [ {v}_{λ} ] [ A ( v + ω ) ]$$

Here, [v_{γ(λ)}] is the “velocity” matrix where each element is associated with the optical transition rate between states represented by the pair of its matrix indices. It is argued, at least approximately, that the velocity matrix elements are non-zero only for the elements connecting the nearest-neighbor s orbitals. Such matrix elements are of the form of ita/ℏ for the upper triangle elements, and −ita/ℏ for the lower triangle elements, with a being the nearest-neighbor distance between Au atoms, which is the magnitude of the fcc primitive lattice vector, t the nearest-neighbor hopping parameter between s orbitals, and i=\sqrt{−1}. Lastly, [A(v)]=−(1/π)Im[G(ω)] is the spectral function matrix.

The interest is only to compute the longitudinal tensor component of the optical conductivity, that is σ_{1γγ}(ω). The γ is taken to be along a₁ (or equivalently a₂), which is referred to as the “in-plane” direction, and along a₃, which is referred to as the “out-of-plane” direction.

For the purpose of further calculations, the imaginary part of the complex optical conductivity tensor σ_{2γγ}(ω) also needs to be calculated through the Kramers-Kronig relation, that is

$${σ}_{2 γ γ} ( ω ) = - \frac{2 ω}{π} P {\int }_{0}^{∞} dv \frac{{σ}_{1 γ γ} ( v )}{{v}^{2} - {ω}^{2}} \qquad ( 11 )$$

### Dielectric Functions

The complex dielectric function \tilde{ε}(ω)=ε₁(ω)+iε₂(ω) can be easily obtained once one has the full information of the complex optical conductivity \tilde{σ}(ω)=σ₁(ω)+iσ₂(ω). The two complex quantities are related through

$$\tilde{ε} ( ω ) = {ε}_{1} ( ∞ ) + i \frac{\tilde{σ} ( ω )}{{ϵ}_{0} ( ω )} \qquad ( 12 )$$

which implies that (taking ε₁(∞)=1)

$${ε}_{1 ( ω )} = 1 - \frac{{σ}_{2} ( ω )}{{ε}_{0} ω} \qquad ( 13 )$$

$${ε}_{2} ( ω ) = \frac{{σ}_{1} ( ω )}{{ε}_{0} ω} \qquad ( 14 )$$

### Loss Function

Physically, loss function (LF(ω)) is defined as the optical quantity showing how strong the effective Coulomb interaction between electrons occurs in the material under the influence of external electromagnetic field at a given frequency ω. Such interactions become strongest when the effective permittivity (i.e. the complex dielectric function) of the medium tends to be singular. For this reason, LF(ω) is defined such that it corresponds to the poles of the complex quantity 1/(ω), that is

$$LF ( ω ) = - Im \frac{1}{\tilde{ε} ( ω )} = \frac{{ε}_{2} ( ω )}{{ε}_{1}^{2} ( ω ) + {ε}_{2}^{2} ( ω )} \qquad ( 15 )$$

The name “loss function” is related to the quantity called “electron energy loss” in experiment called Electron Energy Loss Spectroscopy (EELS), indicating how much an external electron loses its energy, as a function of its initial kinetic energy (= [symbol] ω), when it passes through a material. In EELS, the function LF(ω) measures the relative distribution of energy loss of the electron beam after passing through the material. In optical spectroscopy, LF(ω) measures the relative distribution of photon energy driving electron collective motions. In both spectroscopies, the peaks in LF(ω) correspond to the emergence of electron collective oscillatory motions referred to as plasmons.

### Reflectance

Another optical quantity one can compute from the complex dielectric function is the reflectance, R(ω). For normal incidence, this function can be obtained through

$$R ( ω ) = {\vert \frac{\sqrt{\tilde{ε} ( ω )} - 1}{\sqrt{\tilde{ε} ( ω )} + 1} \vert}^{2} \qquad ( 16 )$$

### Results and Discussion Using the Model for an Example Embodiment

The following fixed parameter values were used: t=1 eV, U=2 eV, ∈ₛ=0 eV, ∈_{d}=−3 eV, and a˜4 Å. In most calculation results presented here, the system size is taken to M×M×N with M=11, while N may be varied from 2 to 6. The main reason for taking M=11 is because it corresponds to a length of (M−1)a˜(11−1)×4 Å˜40 Å, which is of the order of the nanoparticle diametrical length. Another reason is that the system size of Nₛᵢₜₑₛ=11×11×6 reaches the limit of the available computing resource for a reasonable computing time.

### Density of States

The evolution of PDOS with system size, without and with s-d hybridization revealed that the increase in Nₛᵢₜₑₛ slightly increases the s bandwidth and makes PDOS-s become denser. In this model, the choice of values of d and U only affects the position of the center of d band, that is ∈_{deff}=∈_{d}+ [symbol] n_{d} [symbol] _{(↓)} [symbol] U. The presence of s-d hybridization creates splitting in PDOS of both s and d bands, which occurs at the same position, that is at ∈_{deff}. The s-d hybridization and confinement effects (reduction in system size into nanoscale) plays important role to generate the unconventional plasmon in loss function and gap-like in dielectric function.

### Optical Responses

### In-Plane Vs Out-of-Plane Responses

The analysis revealed that the out-of-plane responses resemble the experimental data shown in FIGS. 10 and 12 much better compared to those of the in-plane responses. It was noticed from the peak positions in the theoretical analysis of ε₂(ω), which correspond to the zeros of ε₁(ω) with negative slopes, that they shift to the left as the length along which the measurement is taken.

### Effect of Confinement

The ε₂(ω) peak and correspondingly the zero of ε₁(ω) with negative slope, undergo a blue shift as the length along which the optical measurement is taken decreases. This manifests the effect of confinement. It is interpreted that confinement acts to make the electrons move in a similar manner as if the electrons were bound to the atomic nuclei by some “spring”. This introduces a certain characteristic oscillation frequency, say ω₀. Thus, the peak of ε₂(ω) corresponds to the resonance at this characteristic oscillation frequency. The more the electrons are confined, the more they feel like being more strongly bound to the nuclei, causing ω₀ to increase. It is argued that this kind of electron oscillatory motion generate plasmons unconventionally. To address this, it was carefully inspected whether there is really a peak in the LF(ω) curve corresponding to the peak centred at ω₀ in the ε₂(ω) curve. It was found that, for N=3, a broad peak in ε₂(ω) curve does correspond to the broad peak in the LF(ω) curve in the exact same energy region around 2.25 eV. Such a situation is also found, although not so clearly for N=4. For N=5, this situation can also still be observed, but the corresponding LF(ω) peak is already very weak. For N=6, the corresponding LF(ω) peak is already not visible. Thus, apparently for these LSPs there is a trend whereby as N increases the peak intensity of ε₂(ω) increases, but the intensity of the corresponding LF(ω) peak decreases.

### Effect of s-d Hybridization: Emergence of a New Kind of Unconventional Plasmon

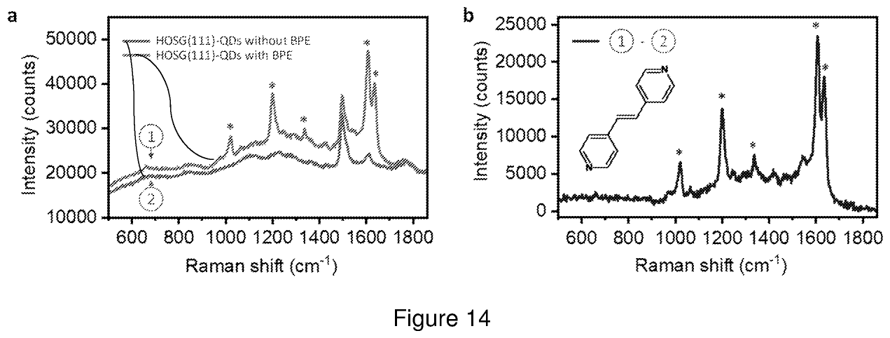

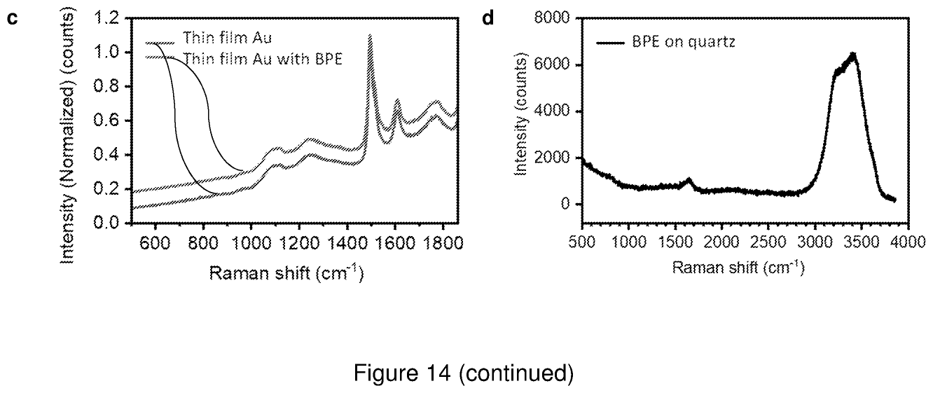

It was discussed how s-d hybridization affects the DOS profile in FIG. 14. This effect is now discussed on the optical responses. From the LF(ω) calculated curves it was found that they have sharper and narrower peaks (˜1.9 eV at N=3, ˜1.8 eV at N=4 and ˜1.3 eV at N=5) arising from unconventional plasmons in this energy range below 2 eV. In the experimental data (see the loss function curves in FIG. 11(a)), the LF peaks at ˜1.65 eV and ˜1.85 eV have a similar character to those of the calculated LF curves at the aforementioned energies. Hence, it is argued that the plasmonic peaks at ˜1.65 eV and 1.85 eV observed in the experimental data of Au/MgO emerges due to s-d hybridization, and this is a new kind of unconventional plasmons that have not been reported before, to the knowledge of the inventors.

### Application of Au-QDs According to Example Embodiments as a SERS-Chip According to an Example Embodiment

A direct and useful technological application of this unique spin correlated-plasmon's property is demonstrated using Au-QDs according to example embodiments as a SERS-chip, i.e. Spin-SERS, with 1,2-Di(4-pyridyl)ethylene (BPE) as the analyte. Intriguingly, strong SERS signals (FIGS. 14(a) raw data, and (b) background subtracted) are observed when 10 μM (1.8 ppm) of BPE dripped and dried on the Spin-SERS chip according to an example embodiment was excited using laser with photon energy of 633 nm (˜1.96 eV), which is resonant at the spin correlated-plasmon. Raman peaks at (i) 1020 cm⁻¹ due to (C—N) and (C—C) stretching modes, (ii) 1200 cm⁻¹ due to (Cᵣ-C_{b}) stretching and rocking modes where Cᵣ is a ring-carbon bonded to a bridging carbon and C_{b} is a bridging-carbon, (iii) 1335 cm⁻¹ due to (C═C) bending modes, and lastly (iv) 1607 cm⁻¹ and 1635 cm⁻¹, which are BPE characteristic peaks due to (C—C) stretching modes were observed. In contrast, no SERS signal is observed using SERS-substrate of Au thin film (FIG. 14(c)) or quartz slide (FIG. 14(d)) with the same analyte, further signifying the unique role of the spin correlated-plasmon generated in Au-QDs according to example embodiments, and not in continuous Au thin film. To further support the high sensitivity of the Spin-SERS chip according to an example embodiment, about 23000 counts were acquired (based on the 1607 cm⁻¹ peak for a 1.8 ppm analyte) within a 3 s integration time and 11 mW laser. It is worthwhile to mention that since currently available SERS-active substrates have fundamental challenges of being either not reproducible or very complex and difficult to prepare, the spin correlated-plasmon in a Spin-SERS chip according to an example embodiment can address and overcome those challenges. The spin correlated-plasmon, a quantum oscillation of an interplay of spin and charge due to electronic correlations in strongly correlated electron systems, opens new applications such as combined spintronic-plasmonic applications, as well as new fundamental science.

### Transfer of Self-Organized Single-Crystal QDs According to Example Embodiments

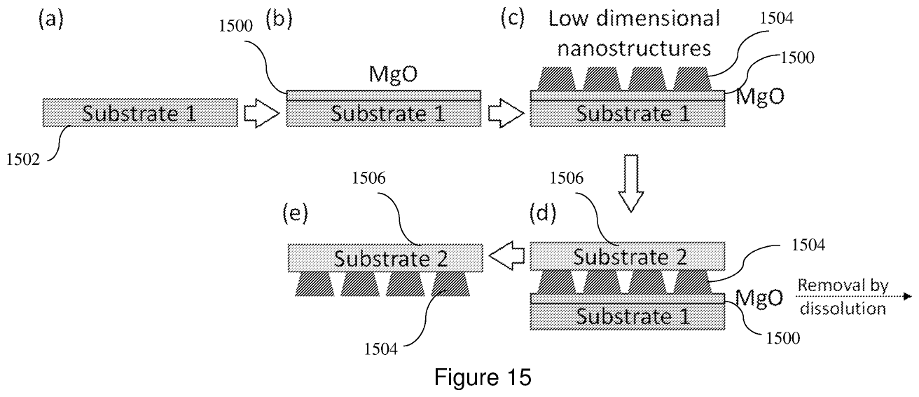

In fabrication of Au QDs using MgO as the substrate in an example embodiment, the low dimensional nanostructures can be easily transferred to other substrates by removing the MgO as illustrated in FIG. 15. This transfer method allows the nanostructures to be transferred to any other substrate which cannot be used in the initial nanostructure fabrication process. Specifically, in FIGS. 15(a) to (b), a thin layer of MgO 1500 is epitaxially deposited as the growth substrate onto a carrier substrate 1502 (e.g. Ge(001)). In FIG. 15(c), low dimensional nanostructures (e.g. Au QDs 1504) are then deposited onto MgO 1500 according to an example embodiment. In FIG. 15(d) s secondary substrate 1506 is bonded to the nanostructures e.g. 1504 from the top and MgO 1500 is removed (by dissolution) using deionized water, which leads to a complete transfer of the nanostructures e.g. 1504 to substrate 1506 shown in FIG. 15(e).

As described above, self-organized single-crystal transition-metal highly-correlated spin-polarized low dimensional nanostructure can be provided according to an example embodiment. The fabrication method according to an example embodiment is a one-step process combining the formation of transition metal nanostructures with self-organization (self-assembly) on a substrate.

The fabrication method according to an example embodiment uses existing technological platforms (ultra-high vacuum systems) for electronic device fabrication—it can be easily integrated to existing fabrication lines as an additional step without complications. This is a critical step in the fabrication of devices such as sensors as it allows a seamless integration of fabricating low dimensional nanostructures in the electronic device manufacturing process which is mainly carried out in vacuum. This step is not possible with existing methods of low dimensional nanostructures fabrication such as chemical synthesis which requires additional (disruptive) steps requiring devices to be taken out of manufacturing line process.

By virtue of its integrating advantage as described above, the manufacturing process incorporating the fabrication of low dimensional nanostructures according to an example embodiment is therefore fast and streamlined.

An example embodiment can generate the formation of self-organized (self-assembled) array of low dimensional nanostructures on a substrate with fast fabrication process high purity, reproducibility and reliability, sensitivity and selectivity, quantitatively.

By virtue of the tunable shape, size and crystal orientation of low dimensional nanostructures according to example embodiments, device fabrication incorporating the nanostructures (e.g. QDs) according to example embodiments for devices such as sensors can be easily customized according to the requirements of the device specifications.

Embodiments of the present invention can serve as a platform (template) for further newer technological innovations. The 2D array of the nanostructures fabricated according to an example embodiment allows expansion of applications in various fields such as bio-applications. In one example, QDs fabricated according to an example embodiment can be further capped with capping-molecules such as thiols and then used for bio-tagging and binding of specific bio-molecules or bio-entities.

In another example, by virtue of its unique properties (spin-polarized and orbital-ordering), low dimensional nanostructures fabricated according to an example embodiment can serves as a device platform for the development of quantum computers.

### Other Example Embodiments

The selection of materials for growth (i.e. substrate and film layer) leading to formation of well-organized assembly of QDs according to example embodiment are driven by considering the following material selection rules:
(i) Similarity of Crystal structure 2D symmetry (Tetragonal-Square, Hexagonal, Orthorhombic-Rectangular, Orthorhombic-Centered Rectangular, Monoclinic) to promote epitaxy and geometrical control and
(ii) Lattice mis-matched between substrate and the growth layer to facilitate Stranski-Krastanov growth (SK) and/or Volmer-Weber (VW) growth mode.

For example, for FCC Au layer on Cubic MgO substrate, the lattice mismatch is ≈−3.5%. It was found that the larger the mis-match in lattice the greater the probability of forming QDs structure as a strain relief mechanism.

The growth processes (adsorption, nucleation and growth) according to example embodiments are controlled by kinetics and energetics of the material systems. These are in-turn driven by the process parameters i.e. Choice of Temperature, Growth Rates, Oxygen Process Gas, Ultra-High Vacuum (UHV) environment, etc. The recipe for growth of Au on MgO(001) is judiciously developed to promote Au QDs formation on MgO(001) substrate.

The Methodology and Approach used to develop this recipe according to various example embodiment is generic and will be applicable for other growth systems based on the abovementioned material selection criteria.

Therefore, embodiments of the present invention can be extended to Noble metals (e.g. Pt, Au, Cu, Ag), Magnetic Materials (e.g. Fe, Co, Ni), Rare-earth materials (e.g. Er, Dy, Nb etc), as well as non-metals (e.g. Group IV, Group V and Group VI elements) and can thus be templated on e.g. MgO based upon the selection rule and growth methodology developed for Au.

For the underlying oxide substrates, other low index orientation single crystal MgO substrate including (110) and (110) as well as other single crystal oxide substrates can similarly be used in different example embodiments, including, but not limited to, SrTiO₃, LaₓBa₂₋ₓCuO₄, LaAlO₃.

The formation of Au QDs on other substrates other than MgO substrates was successfully achieved according to example embodiments as follows:

Examples of Au QDs formed on other substrates:
1) Apart from Au QDs on MgO(001), Au QDs are also formed on MgO(111) and MgO(110).
2) Au QDs on SrTiO₃(001)
3) Au QDs and Nanowires on Ge(001)
4) Au QDs and Nanowires on La₂₋ₓBaₓCuO_{4+δ}
5) Au on Al₂O₃

Growth temperature is an important factor in making the growth recipe work in different embodiments.

For example, the deposition of Au onto MgO(001) was observed at a growth temperature above about 300° C. Below this temperature, the growth may lead to the formation of polycrystalline Au or amorphous-like Au.

On the other hand, the deposition of Au onto MgO(001) was found to also limited to growth temperatures below about 800° C. At this temperature or higher, Au appears to desorb from MgO(001). Total removal of Au from MgO(001) was found to occur when Au/MgO(001) was annealed at 900° C. for 30 minutes to 1 hour.

It is noted that the range of the temperature for optimal growth of Au QDs also depends on the substrate used.

For example, the temperature range for PLD of Au on MgO(001) was found to be between about 300 and 800° C., while the temperature range for PLD of Au on Ge(001) was found to be between about 300 and 700° C., due to the relatively lower melting temperature of Ge (938° C.) as compared to MgO (2852° C.).

An example preferred range of parameters according to an example embodiment was found as follow:
1) Growth Temperatures: 300-800° C. (for MgO substrates)
2) Pulsed Laser Deposition parameters*:
   a. Pulsed Frequency: 1-10 Hz
   b. O₂ partial pressure: 0-100 mTorr
   c. Laser used: Nd:YAG (Output wavelength 266 nm); KrF Excimer laser (Output wavelength 248 nm)
   d. Laser energy: 1-5 Jcm⁻²
   e. Number of pulses: 0-10,000 pulses

*These parameters may differ slightly with different PLD systems.

### Growth Techniques According to Example Embodiments

The present invention includes applying Physical Vapor Deposition techniques which include Pulsed Laser Deposition, Sputtering, Molecular Beam Epitaxy, Electron-beam Evaporation, where the formation of the desired material QDs was found to be relatively more direct.

This is in contrast to other techniques such as Chemical Vapor Deposition techniques where growth of materials involves the use of precursors which react at the substrate surface forming the desired material product on the surface.

### Material Systems According to Example Embodiment

The present invention includes applying the formation of self-assembled crystalline metal QDs which includes, but is not limited to, noble metals such as Au, Ag, Pd, Cu and Pt.

It is noted that QDs consisting of binary systems such as AuAg, AuPd or ternary systems such as AuAgCu may also be included according to example embodiment.

Choice of substrates according to example embodiment follows from the growth behavior of the metal QDs, i.e. with suitable lattice matching substrates allowing for the formation of self-assembled single-crystalline QDs.

In one embodiment, a method of fabricating low dimensional nanostructures on a growth substrate using physical vapor deposition, PVD, in a vacuum chamber is provided, wherein the low dimensional nanostructures are formed as a strain relief mechanism promoted by a similarity of crystal structure 2-dimensional symmetry between the growth substrate and the low dimensional nanostructures to be grown and a lattice mismatch between the growth substrate and the low dimensional nanostructures to be grown.

The method may comprise controlling shape and crystal orientation of the low dimensional nanostructures by choosing a surface orientation of the growth substrate.

The method may comprise controlling a size of the low dimensional nanostructures by choosing a growth temperature. The growth temperature may be chosen to be high enough to promote the strain relief mechanism and low enough to avoid desorption from the growth substrate.

The method may comprise using over pressure conditions during the PVD to control the shape and crystal orientation of the low dimensional nanostructures. The over pressure condition may comprise using one or more of a group consisting of O2, N2, and Ar.

The method may comprise transferring the low dimensional nanostructure from the growth substrate to a secondary substrate.

The low dimensional nanostructures may comprise noble metals, magnetic materials, rare-earth materials, as well as non-metals.

The noble metals may comprise one of more of a group consisting of Pt, Au, Cu, Ag.

The magnetic materials may comprise one of more of a group consisting of Fe, Co, Ni.

The rare-earth materials may comprise one of more of a group consisting of Er, Dy, Nb.

The non-metals may comprise one of more of a group consisting of Group IV, Group V and Group VI elements.

The method may comprise the steps of:
annealing the growth substrate to a first temperature;
cooling the growth substrate to a second temperature lower than the first temperature;
performing the PVD at the second temperature for growing the low dimensional nanostructures; and
cooling the substrate to room temperature.

The second temperature may be in a range from about 300° C. and 800° C.

The first temperature may be about 900° C.

The method may comprise cleaning a target for the PVD prior to performing the PVD at the second temperature for growing the low dimensional nanostructures.

The PVD may comprise pulsed laser deposition, PLD. The PLD may be performed with a pulsed frequency in a range from about 1-10 Hz, with an O₂ partial pressure of about 0-100 mTorr, with a laser energy of about 1-5 Jcm⁻², and a number of pulses from about 0-10,000 pulses. The method may comprise using a Nd:YAG laser with an output wavelength of about 266 nm) or a KrF Excimer laser with an output wavelength of about 248 nm.

The low dimensional nanostructures may be Au quantum dots. The growth substrate may be MgO.

In one embodiment, a single-crystalline low dimensional nanostructure exhibiting an electron-electron interaction based splitting in partial density of states of electron bands of the low dimensional nanostructures is provided.

The low dimensional nanostructure may exhibit a ferromagnetic property results from spin polarization of the low dimensional nanostructure.

The low dimensional nanostructure may be an Au quantum dot. The electron bands may comprise Au 6s and Au 5d.

In one embodiment, a device comprising one or more single-crystalline low dimensional nanostructures, wherein a response of the device is based on electron-electron interaction based splitting in partial density of states of electron bands of the low dimensional nanostructures is provided.

The response may be based on optical properties of the low dimensional nanostructures resulting from the electron-electron interaction based splitting in partial density of states of the electron bands of the low dimensional nanostructures. The response may be based on plasmons resulting from the electron-electron interaction based splitting in partial density of states of the electron bands of the low dimensional nanostructures.

The response may be based on ferromagnetic properties of the low dimensional nanostructures resulting from spin polarization of the low dimensional nanostructure.

The low dimensional nanostructures may be Au quantum dots. The electron bands may comprise Au 6s and Au 5d.

The device may be configured for use in one or more of a group consisting of (i) as a chip for surface enhanced Raman spectroscopy (SERS) and otherplasmonic applications, (ii) as a chip for sensors utilizing its unique magnetic (spintronics) properties (iii) and optical properties, (iv) optoelectronic properties, (v) as a chip for biological applications such as bio-sensors, bio-tagging and bio-imaging, in applications for (vi) energy harvesting, (vii) catalyses, (viii) plasmonic lithography, and in (ix) quantum-computing.

### Embodiments of the Present Invention can have One or More of the Following Features and Associated Benefits/Advantages

| Feature | Benefit/Advantage |
|---|---|
| Single-step fabrication process | Method according to an example embodiment does |
| | not require complex pre-fabrication treatments such |
| | as chemical reagent preparations. |
| | Method according to an example embodiment does |
| | not require complex post-fabrication treatments |
| | including, but not limiting to, removal of residual |
| | reactants and precursors, purification, self-assembly |
| | processes such as Langmuir-Blodgett technique or |
| | through the use of nano-lithography. |
| | Method according to an example embodiment does |
| | not require encapsulation using surfactants. |
| | Method according to an example embodiment can |
| | be integrated or incorporated into existing device |
| | fabrication process. |
| Single-crystalline QDs with tunable | Allows control with precision in the fabrication of |
| crystal-orientation, QD-shape and | low dimensional nanostructures in terms of their |
| QD-size | shape, crystal-direction and size. |
| Self-organized (self-assembled) | Bottom-up approach which avoids the need of |
| pattern | lithographic stencils to create patterns/templates. |
| | By this approach, the method according to an |
| | example embodiment is a plasmonic lithographic |
| | process. |
| Exhibit different colors customizable | Colors of the nanostructures according to an |
| by controlling growth parameters | example embodiment obtained can be used as |
| such as nanostructure size, shape and | sensors for diverse applications. Properties |
| oxidation states. | associated with the colors of the nanostructures |
| | according to an example embodiment such as peak |
| | absorbance allow sensitivity and selectivity in |
| | signal responses with fast detection. |
| Exhibit unique properties such as | Nanostructures (e.g. Au QDs) fabricated according |
| ferromagnetism and | to an example embodiment are shown to possess |
| superconductivity | unique properties (namely spin-polarization and |
| | orbital ordering) that are not reported in similar |
| | nanostructures fabricated through other means. This |
| | unique magnetic property, for instance, allows the |
| | fabrication of nanostructures that can be |
| | biocompatible without the need to combine with |
| | other magnetic materials such as Fe, Co or Ni which |
| | are not biocompatible. |
| Enables transfer of self-organized | Allows the fabrication of self-organized (self- |
| single crystal nanostructures onto | assembled) single-crystalline nanostructures such |
| other substrates | as QDs onto any substrate surface which cannot be |
| | used for the fabrication of the nanostructures. |
| Serves as a platform for further | Makes use of the nanostructure assembly according |
| applications | to an example embodiment to create further |
| | innovations. For instance, the assembly according |
| | to an example embodiment can be used for bio- |
| | applications (e.g. bio-tagging or bio-stamping). |

### Materials and Methods According to Non-Limiting Example Embodiments

### Sample Preparation

Highly oriented single crystal gold quantum dots (AU-QDs) were prepared on 1 cm×1 cm MgO(001) substrates by ultra-high vacuum molecular beam epitaxy pulsed laser deposition (UHV MBE PLD system) equipped with a solid-state ablation Nd:YAG laser (laser output wavelength 266 nm) and growth monitoring using in-situ reflection high-energy electron diffraction (in-situ RHEED). Each MgO(001) substrate was loaded as received into the UHV MBE PLD system with a base pressure of 1.5×10⁻⁸ Torr. The substrate was subsequently outgassed at 310° C. for 1 hour before annealing at 900° C. for another 30 mins to obtain a clean MgO(001) surface as verified using in-situ RHEED. Prior to Au deposition, the substrate was first brought to the growth temperature. The Au target was laser-ablated using 1000 pulses at 10 Hz frequency. 500 pulses of Au were then deposited at the growth temperature with a PID-controlled O₂ partial pressure (0 mTorr or 10 mTorr). The laser energy is fixed at about 3.25 Jcm⁻² for all depositions with a frequency of 1 Hz. The samples were annealed for a further 30 mins under the same growth temperature and oxygen partial pressure before being cooled down to room temperature. All temperature ramps were fixed at 25° C. min⁻¹.

### Analysis of Spectroscopic Ellipsometry (SE) Results

For the analysis of the ellipsometry results, the amplitude (Ψ(ω)) and phase difference (Δ(ω)) reflected from the sample are fitted using commercially available WVASE software from J.A. Woolam. Optical models are built to fit Ψ(ω) and Δ(ω) to obtain precise complex dielectric function of thin film Au and Au-QDs according to example embodiments. Thin film Au is modelled as a continuous film with thickness estimated from XRD results.

For both thin film Au and AU-QDs according to example embodiments, several oscillator functions are used in the fitting of spectroscopic ellipsometry data. To model the Drude response in thin film Au, Lorentz oscillators are used to mimic the behaviour of free electrons in metals. In addition, Gaussian and PSEMI-Tri oscillators are also employed to obtain a good fit throughout whole photon energy range. For AU-QDs, a combination of Gaussian, and PSEMI-Tri oscillator functions are used instead. PSEMI-Tri is a highly flexible, Kramers-Kronig consistent, oscillator function developed by Herzinger and Johs.

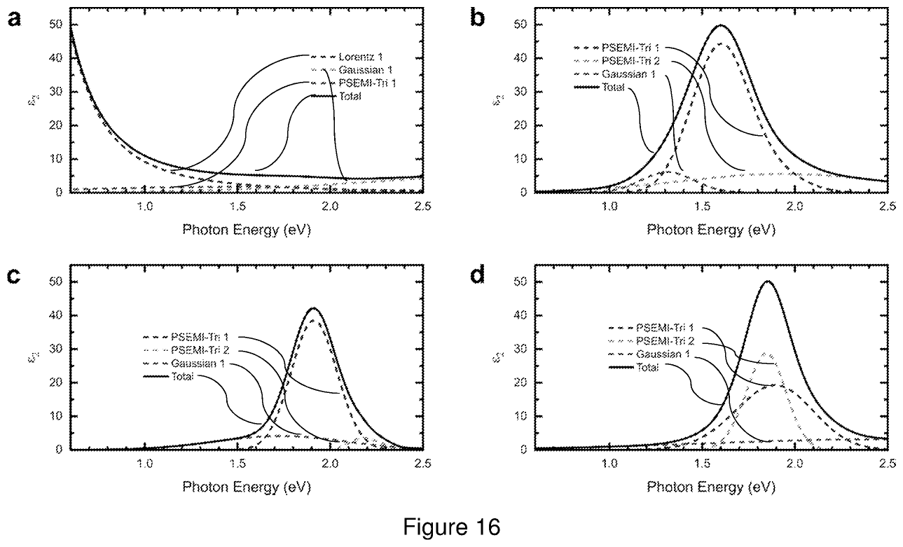

The oscillator functions used to fit the ellipsometric data are shown in FIG. 16. ε₂ (ω) is fitted using Lorentzian, Gaussian, or PSEMI-Tri oscillators until it reaches convergence. ε₁(ω) is fitted by varying the magnitude of the poles (zero-width Lorentz oscillators) representing absorption occurring beyond the measured spectral range. The MSE for all measured thin films and Au-QDs according to example embodiments ranges between 1.5-2.1. The oscillator functions are shown in FIG. 16(a) for thin Film Au, FIG. 16(b) for 650° C. Au(111)-QDs, FIG. 16(c) for 650° C. Au(001)-QDs and FIG. 16(d) for 750° C. Au(111)-QDs.

A good quality of fit was observed by comparing the modelled Ψ(ω) and Δ(ω) values against the obtained ellipsometric data for thin film Au, for 650° C. Au(111)-QDs, for 650° C. Au(001)-QDs and for 750° C. Au(111)-QDs.

The above description of illustrated embodiments of the systems and methods is not intended to be exhaustive or to limit the systems and methods to the precise forms disclosed. While specific embodiments of, and examples for, the systems components and methods are described herein for illustrative purposes, various equivalent modifications are possible within the scope of the systems, components and methods, as those skilled in the relevant art will recognize. The teachings of the systems and methods provided herein can be applied to other processing systems and methods, not only for the systems and methods described above.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive. Also, the invention includes any combination of features described for different embodiments, including in the summary section, even if the feature or combination of features is not explicitly specified in the claims or the detailed description of the present embodiments.

In general, in the following claims, the terms used should not be construed to limit the systems and methods to the specific embodiments disclosed in the specification and the claims but should be construed to include all processing systems that operate under the claims. Accordingly, the systems and methods are not limited by the disclosure, but instead the scope of the systems and methods is to be determined entirely by the claims.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

1. A method of fabricating low dimensional nanostructures on a growth substrate, the method comprising:
using physical vapor deposition, PVD, in a vacuum chamber to grow low dimensional nanostructures comprising:
annealing a growth substrate to a first temperature;
cooling the growth substrate to a second temperature lower than the first temperature;
performing PVD at the second temperature for growing low dimensional nanostructures; and
cooling the substrate to room temperature,
wherein the step of growing the low dimensional nanostructures comprising:
controlling shape and crystal orientation of the low dimensional nanostructures by choosing a surface orientation of the growth substrate;
controlling size of the low dimensional nanostructures by choosing a growth temperature;
using over pressure conditions during the PVD to control the shape and crystal orientation of the low dimensional nanostructures, wherein the over pressure conditions comprise using one or more of a group consisting of O2, N2, and Ar; and
wherein the low dimensional nanostructures are formed as a strain relief mechanism promoted by a similarity of crystal structure 2-dimensional symmetry between the growth substrate and the low dimensional nanostructures to be grown and a lattice mismatch between the growth substrate and the low dimensional nanostructures to be grown, and
wherein the growth temperature is chosen to be high enough to promote the strain relief mechanism and low enough to avoid desorption from the growth substrate.

2-6. (canceled)

7. The method of claim 1, further comprising transferring the low dimensional nanostructure from the growth substrate to a secondary substrate.

8. The method of claim 1, wherein the low dimensional nanostructures comprise noble metals, magnetic materials, rare-earth materials, as well as non-metals.

9. The method of claim 8, wherein the noble metals comprise one of more of a group consisting of Pt, Au, Cu, Ag.

10. The method of claim 8, wherein the magnetic materials comprise one of more of a group consisting of Fe, Co, Ni.

11. The method of claim 8, wherein the rare-earth materials comprise one of more of a group consisting of Er, Dy, Nb.

12. The method of claim 8, wherein the non-metals comprise one of more of a group consisting of Group IV, Group V and Group VI elements.

13. (canceled)

14. The method of claim 1, wherein the second temperature is in a range from 300° C. and 800° C.

15. The method of claim 1, wherein the first temperature is about 900° C.

16. The method of claim 1, further comprising cleaning a target for the PVD prior to performing the PVD at the second temperature for growing the low dimensional nanostructures.

17. The method of claim 1, wherein the PVD comprises pulsed laser deposition, PLD.

18. The method of claim 17, wherein the PLD is performed with a pulsed frequency in a range from 1-10 Hz, with an O₂ partial pressure of 0-100 mTorr, with a laser energy in a range of 1-5 Jcm⁻², and a number of pulses from 0-10,000 pulses.

19. The method of claim 18, further comprising using a Nd:YAG laser with an output wavelength of about 266 nm or a KrF Excimer laser with an output wavelength of about 248 nm.

20. The method of claim 1, wherein the low dimensional nanostructures are Au quantum dots.

21. The method of claim 20, wherein the growth substrate is a crystalline metal-oxide substrate selected from a group consisting of MgO, La₂₋ₓBaₓCuO_{4+δ}, LaAlO₃, SrTiO₃.

22-32. (canceled)
